(19) United States
(12) Patent Application Publication
(10) Pub. No.: US 2023/0141281 A1
(43) Pub. Date: May 11, 2023

(54) SUBSTRATE PROCESSING DEVICE AND METHOD

(71) Applicant: JUSUNG ENGINEERING CO., LTD., Gwangju-Si, Gyeonggi-Do (KR)

(72) Inventors: Chang Kyun PARK, Gwangju-Si, Gyeonggi-Do (KR); Yong Hyun KIM, Gwangju-Si, Gyeonggi-Do (KR); Chul Joo HWANG, Gwangju-Si, Gyeonggi-Do (KR)

(21) Appl. No.: 17/917,547

(22) PCT Filed: Mar. 30, 2021
(86) PCT No.: PCT/KR2021/003946

§ 371 Date: Oct. 6, 2022

(30) Foreign Application Priority Data
Apr. 10, 2020 (KR) 10-2020-0044156

(51) Int. Cl. C23C 16/44; H01L 21/02

(52) U.S. Cl. CPC C23C 16/4405; H01L 21/02565; H01L 21/0262

(57) ABSTRACT

The device for processing a substrate according to an embodiment of the present disclosure includes a chamber, a substrate supporting unit which is provided inside the chamber and supports a substrate provided inside the chamber, a gas distribution unit which is provided inside the chamber to face the substrate supporting unit and distributes a process gas toward the substrate supporting unit, a first temperature control unit which is installed in a central region of the gas distribution unit and increases a temperature of the central region, and a second temperature control unit which is installed in an edge region of the gas distribution unit and increases a temperature of the edge region more rapidly than the temperature of the central region.

### TECHNICAL FIELD

The present disclosure relates to a device and method for processing a substrate, and more particularly, to a device and method for processing a substrate, by which a thin film is deposited on a substrate and a byproduct accumulated during a deposition process is removed.

### BACKGROUND ART

Generally, various materials are deposited on a substrate in the form of thin film and then patterned, thereby manufacturing a semiconductor element. To this end, several operations of different processes such as a deposition process, an etching process, a cleaning process, and a drying process are performed. Here, the deposition process is to form, on the substrate, a thin film having properties required as a semiconductor element. However, during the deposition process for forming the thin film, a byproduct including a deposition material is deposited not only on a region of interest on the substrate but also inside a chamber in which the deposition process is performed.

The byproducts accumulated inside the chamber are peeled off when the thickness thereof increases, which causes the generation of particles. The particles generated as described above enter a thin film formed on the substrate or are attached to the surface of the thin film, causing defects of the semiconductor element and thereby increasing the defect rate of a product. Thus, it is necessary to remove the byproducts deposited inside the chamber before the byproducts are peeled off.

With regard to metal-organic chemical vapor deposition (MOCVD), a chamber cleaning process is performed periodically to remove byproducts which are accumulated inside the chamber during the deposition process. In a device for processing a substrate which performs the MOCVD, the byproducts inside the chamber may be removed by a wet etching method using a cleaning solution or by a dry etching method using a cleaning gas. When metal is included in the byproducts accumulated inside the chamber, it is frequently not easy to perform the dry etching using the cleaning gas. Thus, in the device for processing a substrate which performs the MOCVD, the inside of the chamber is cleaned generally by the wet etching. In the cleaning performed by the wet etching, it is common that an operator manually performs cleaning by oneself in a state in which the chamber is open. Thus, cleaning costs are increased, and it is difficult to ensure the reproducibility and operating ratio of equipment.

### Related Art Documents

(Patent document 1) KR10-2011-0074912 A

### DISCLOSURE OF INVENTIVE CONCEPT

### Technical Problem

The present disclosure provides a device and method for processing a substrate, capable of efficiently cleaning a chamber, in which a byproduct is accumulated, after depositing a thin film on a substrate.

The present disclosure also provides a device and method for processing a substrate, capable of efficiently cleaning a byproduct that includes metal accumulated inside a chamber after performing MOCVD.

### Technical Solution

In accordance with an exemplary embodiment, a device for processing a substrate includes: a chamber; a substrate supporting unit provided inside the chamber and configured to support a substrate provided inside the chamber; a gas distribution unit provided inside the chamber to face the substrate supporting unit and configured to distribute a process gas toward the substrate supporting unit; a first temperature control unit installed in a central region of the gas distribution unit and configured to increase a temperature of the central region; and a second temperature control unit installed in an edge region of the gas distribution unit and configured to increase a temperature of the edge region more rapidly than the temperature of the central region.

In accordance with another exemplary embodiment, a device for processing a substrate includes: a chamber; a substrate supporting unit provided inside the chamber and configured to support a substrate provided inside the chamber; a gas distribution unit provided inside the chamber to face the substrate supporting unit and configured to distribute a process gas toward the substrate supporting unit; a first temperature control unit installed in a central region of the gas distribution unit and configured to increase and decrease a temperature of the central region; and a second temperature control unit installed in an edge region of the gas distribution unit and configured to increase a temperature of the edge region.

The second temperature control unit may heat the gas distribution unit to a higher temperature than does the first temperature control unit.

The first temperature control unit may include: a flow channel configured to allow a temperature controlling fluid to flow inside the central region; an inlet configured to supply the temperature controlling fluid to the flow channel; and an outlet configured to discharge the temperature controlling fluid from the flow channel.

The second temperature control unit may include an electric heating wire buried inside the edge region.

In accordance with yet another exemplary embodiment, a method for processing a substrate includes: depositing a thin film on a substrate in a chamber in which a gas distribution unit is provided; increasing a temperature of a central region of the gas distribution unit at a first temperature increase rate; increasing a temperature of an edge region of the gas distribution unit at a second temperature increase rate higher than the first temperature increase rate; and supplying a cleaning gas into the chamber to clean the chamber.

The increasing of the temperature of the central region and the increasing of the temperature of the edge region may be performed simultaneously.

The increasing of the temperature of the central region may include allowing a heating fluid to flow in the central region, thereby increasing the temperature of the central region, and the increasing of the temperature of the edge region may include heating an electric heating wire buried in the edge region, thereby increasing the temperature of the edge region.

The cleaning of the chamber may be performed while the temperatures of the gas distribution unit are maintained constant for all the regions or while the temperature of the edge region is maintained higher than that of the central region.

A byproduct on the thin film or inside the chamber may include a metal oxide.

### Advantageous Effects

In accordance with a device and method for processing a substrate of an exemplary embodiment, the temperature changing rates of the gas distribution unit 300 are controlled differently for the regions, and thus the inside of the chamber 100 having non-uniform temperature distribution during the thin film deposition process may be quickly controlled to the uniform temperature prior to performing the cleaning process.

Accordingly, it is possible to maximize the cleaning efficiency of the cleaning process for removing the byproduct accumulated inside the chamber 100, and particularly, it is possible to efficiently clean the byproduct including the metal accumulated inside the chamber 100 of the substrate processing device that performs MOCVD.

Also, in the substrate processing device and the substrate processing method according to the embodiment of the present disclosure, it is possible to perform the in-situ cleaning without opening the chamber 100 in the chemical vapor deposition process that requires frequent cleaning. Thus, the operation efficiency may be improved, and the high reproducibility and operating ratio of equipment may be ensured.

### BRIEF DESCRIPTION OF THE DRAWINGS

FIG. 1 is a view schematically showing a device for processing a substrate according to an embodiment of the present disclosure;

FIG. 2 is a view showing a state in which a thin film is deposited in the device for processing a substrate according to an embodiment of the present disclosure;

FIG. 3 is a view showing a gas distribution unit and a temperature controlling unit according to an embodiment of the present disclosure;

FIG. 4 is a view showing a state in which a temperature of a gas distribution unit is controlled according to an embodiment of the present disclosure; and

FIG. 5 is a view schematically showing a method for processing a substrate according to an embodiment of the present disclosure.

### DETAILED DESCRIPTION

Hereinafter, embodiments of the present disclosure will be described in detail with reference to the accompanying drawings. The present disclosure may, however, be embodied in different forms and should not be construed as limited to the embodiments set forth herein. Rather, these embodiments of the present disclosure are provided so that this disclosure will be thorough and complete, and will fully convey the scope of the present disclosure to those skilled in the art. In the figures, the dimensions of layers and regions are exaggerated for clarity of illustration. Like reference numerals refer to like elements throughout.

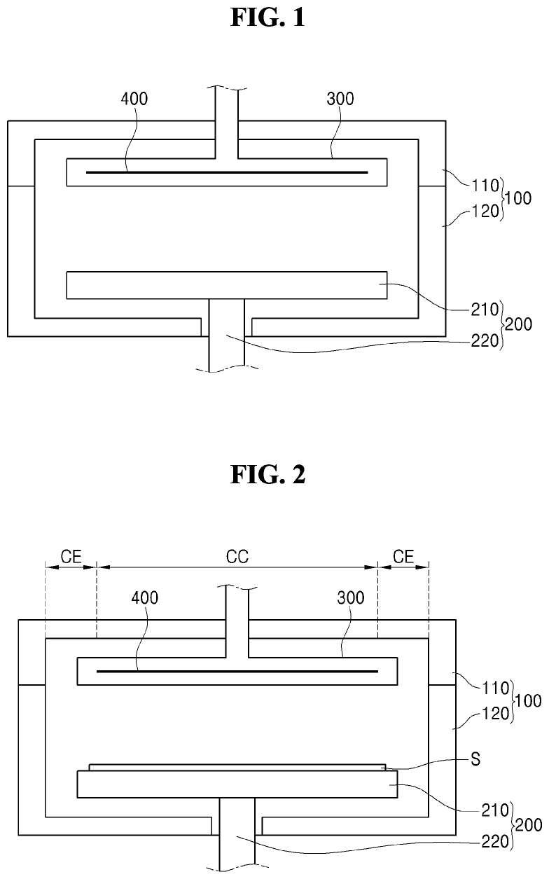

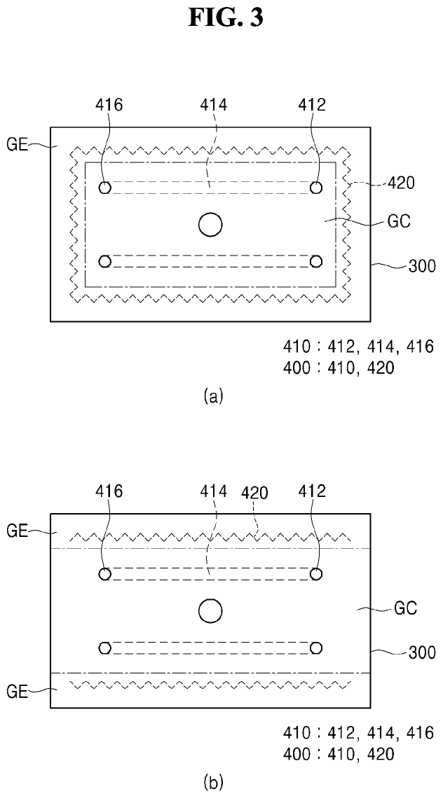

FIG. 1 is a view schematically showing a device for processing a substrate according to an embodiment of the present disclosure. Also, FIG. 2 is a view showing a state in which a thin film is deposited in the device for processing a substrate according to an embodiment of the present disclosure, and FIG. 3 is a view showing a gas distribution unit and a temperature controlling unit according to an embodiment of the present disclosure.

Referring to FIGS. 1 to 3, a device for processing a substrate (hereinafter, referred to as a substrate processing device) according to an embodiment of the present disclosure includes a chamber 100, a substrate supporting unit 200 which is provided inside the chamber 100 and supports a substrate S provided inside the chamber 100, a gas distribution unit 300 which is provided inside the chamber 100 to face the substrate supporting unit 200 and distributes a process gas toward the substrate supporting unit 200, a first temperature control unit 410 which is installed in a central region GC of the gas distribution unit 300 to increase a temperature of the central region GC, and a second temperature control unit 420 which is installed in an edge region GE of the gas distribution unit 300 to increase a temperature of the edge region GE more rapidly than the temperature of the central region GC.

Also, a substrate processing device according to an embodiment of the present disclosure includes a chamber 100, a substrate supporting unit 200 which is provided inside the chamber 100 and supports a substrate S provided inside the chamber 100, a gas distribution unit 300 which is provided inside the chamber 100 to face the substrate supporting unit 200 and distributes a process gas toward the substrate supporting unit 200, a first temperature control unit 410 which is installed in a central region GC of the gas distribution unit 300 to increase or decrease a temperature of the central region GC, and a second temperature control unit 420 which is installed in an edge region GE of the gas distribution unit 300 to increase a temperature of the edge region GE.

Here, when a cleaning cycle for the chamber 100 arrives, the substrate processing device according to an embodiment of the present disclosure may consecutively perform a cleaning process in a vacuum without opening the chamber 100 after completing a thin film deposition process. That is, the substrate S is input into the chamber 100, and a thin film is deposited on the substrate S. When the thin film deposition process is completed, the substrate S is discharged from the chamber 100, and then the cleaning process for cleaning the inside of the chamber 100 is performed consecutively. When the cleaning process is completed, another substrate S is input into the chamber 100, and the thin film deposition process may be performed again. This process is performed in the chamber 100 without a change from a pressure condition for performing the thin film deposition process to a pressure condition that is a condition for opening the chamber 100.

Here, the thin film deposition process is a process for depositing, on the substrate S, a zinc (Zn) oxide doped with at least one of indium (In) or gallium (Ga), for example, a metal oxide such as IZO, GZO, or IGZO. In this case, a byproduct accumulated inside the chamber 100 may include a metal oxide such as a zinc oxide doped with at least one of indium (In) or gallium (Ga).

The chamber 100 provides a predetermined reaction space, and this space is airtightly sealed. Also, the chamber 100 may include: a body 120 having a predetermined reaction space with both an approximately quadrangular flat portion and a sidewall extending upward from the flat portion; and a cover 110 having an approximately quadrangular shape and positioned on the body 120 to airtightly seal the reaction space of the chamber 100. However, the chamber 100 may be manufactured in various shapes corresponding to the shape of the substrate S.

An exhaust port (not shown) may be provided in a predetermined region on the bottom surface of the chamber 100, and an exhaust pipe (not shown) connected to the exhaust port may be provided on the outside of the chamber 100. Also, the exhaust pipe may be connected to the exhaust device (not shown). A vacuum pump such as a turbo-molecular pump may be used as the exhaust device. Thus, the inside of the chamber 100 may be vacuum-suctioned by the exhaust device to a predetermined decompressed atmosphere, for example, to predetermined pressure of about 0.1 mTorr or less. The exhaust pipe may be installed on not only the bottom surface of the chamber 100 but also a side surface of the chamber 100 below a substrate supporting unit 200 which will be described later. Also, a plurality of exhaust pipes and exhaust devices corresponding thereto may be further installed to reduce an exhaust time.

The substrate supporting unit 200 is provided inside the chamber 100 and supports the substrate S provided into the chamber 100. The substrate supporting unit 200 may be installed at a position facing the gas distribution unit 300 which will be described later. For example, the substrate supporting unit 200 may be provided on a lower side within the chamber 100, and the gas distribution unit 300 may be on an upper side within the chamber 100.

Here, the substrate S provided into the chamber 100 for a thin film deposition process may be placed on the substrate supporting unit 200. Also, the substrate supporting unit 200 may be provided with, for example, an electrostatic chuck so that the substrate S is placed and supported, and thus the substrate S may be suctioned and held by an electrostatic force. Alternatively, the substrate S may be supported by vacuum suction or a mechanical force.

The substrate supporting unit 200 may include: a substrate support 210 which has a shape corresponding to the shape of the substrate S, for example, a quadrangular shape and on which the substrate S is placed; and an elevator 220 which is disposed below the substrate support 210 to raise and lower the substrate support 210. Here, the substrate support 210 may be manufactured larger than the substrate S. The elevator 220 is provided to support at least one region of the substrate support 210, for example, a central portion, and the substrate support 210 may be moved close to the gas distribution unit 300 by the elevator 220 when the substrate S is placed on the substrate support 210. Also, a heater (not shown) may be installed in the substrate support 210. The heater generates heat with a predetermined temperature to heat the substrate support 210 and the substrate S placed on the substrate support 210, and thus a thin film is uniformly deposited on the substrate S.

The gas distribution unit 300 is provided on the upper side within the chamber 100 to distribute a process gas toward the substrate S. Also, the gas distribution unit 300 may distribute a cleaning gas into the chamber 100. That is, the gas distribution unit 300 may distribute the process gas toward the substrate S during the thin film deposition process and may distribute the cleaning gas into the chamber 100 during the cleaning process. The gas distribution unit 300 described above may be provided as a showerhead type.

The gas distribution unit 300 has a predetermined space therein. A gas supply unit (not shown) is connected to an upper portion of the gas distribution unit 300, and a plurality of distribute holes (not shown) for distribution the process gas onto the substrate S are provided in a lower portion thereof. The gas distribution unit 300 may be manufactured in a shape corresponding to that of the substrate S and may be manufactured in an approximately quadrangular shape. Here, the gas distribution unit 300 may be manufactured using an electrically conductive material such as aluminum and may be spaced a predetermined distance from a side wall portion of the chamber 100 and the cover 110. When the gas distribution unit 300 is manufactured from the electrically conductive material, the gas distribution unit 300 may serve as an upper electrode that receives power from a plasma generating unit (not shown).

As illustrated in FIG. 2, during the thin film deposition process, the substrate S is placed on the substrate supporting unit 200, and the process gas is distributed from the gas distribution unit 300. Here, the process gas is thermally decomposed on the substrate S and deposited as a thin film. As described above, the heater is installed in the substrate supporting unit 200. Here, the heater generates heat with a predetermined temperature to heat the substrate support 210 and the substrate S placed on the substrate support 210. Thus, the substrate S is uniformly heated by the heater, and the thin film may be uniformly deposited on the substrate S.

Here, the chamber 100 is also heated by the heat generation of the heater during the thin film deposition process. That is, when the substrate support 210 is heated by the heater, the heat generated from the substrate support 210 is transmitted to the chamber 100 due to convection or the like. Accordingly, the chamber 100 becomes heated. However, since the substrate support 210 is provided in a lower central portion within the chamber 100 as described above, amounts of the heat generated from the substrate support 210 and transmitted to the chamber 100 are different for regions. For example, a relatively small amount of heat is transmitted from the substrate support 210 to an edge region CE of the cover 110, which is a region adjacent to a side wall portion of the chamber 100 on the bottom surface of the cover 110, and thus the edge region CE is heated at a relatively low temperature. On the other hand, a relatively large amount of heat is transmitted from the substrate support 210 to a central region CC of the cover 110, which is a remaining region except for the edge region CE of the cover 110 on the bottom surface of the cover 110, and thus the central region CC is heated at a relatively high temperature.

When the thin film deposition process is completed, the cleaning process for cleaning the inside of the chamber 100 is performed consecutively. Here, during the cleaning process, the cleaning gas is supplied into the chamber 100, and a byproduct accumulated inside the chamber 100 is dry-etched and removed. However, as described above, the edge region CE of the cover 110 is heated at a relatively low temperature while the central region CC of the cover 110 is heated at a relatively high temperature. Thus, the chamber 100 has different temperatures for regions, and a difference in etch rates occurs. That is, the edge region CE of the cover 110 is heated at a relatively low temperature and has a low etch rate, but the central region CC of the cover 110 is heated at a relatively high temperature and has a high etch rate. Thus, the byproduct accumulated inside the chamber 100 may not be uniformly etched.

During the cleaning process performed after the thin film deposition process, the cleaning process is performed by heating the gas distribution unit 300 such that the temperature inside the chamber 100 is maintained higher than the temperature for the thin film deposition process. A temperature controlling unit 400 may be installed in the gas distribution unit 300, and the temperature controlling unit 400 heats the gas distribution unit 300 to increase the temperature inside the chamber 100.

Here, in order to uniformly etch the byproduct accumulated inside the chamber 100, the substrate processing device according to an embodiment of the present disclosure includes the first temperature control unit 410 which is installed in the central region GC of the gas distribution unit 300 to increase the temperature of the central region GC and the second temperature control unit 420 which is installed in the edge region GE of the gas distribution unit 300 to increase the temperature of the edge region GE more rapidly than the temperature of the central region GC.

As illustrated in FIG. 3, the gas distribution unit 300 is divided into the edge region GE of the gas distribution unit 300 adjacent to the side wall portion of the chamber 100 and the central region GC of the gas distribution unit 300. Here, the edge region GE of the gas distribution unit 300 may be the entire edge regions along the outer peripheral side of the gas distribution unit 300 as illustrated in (a) of FIG. 3, or may be partial edge regions along the outer peripheral side of the gas distribution unit 300 as illustrated in (b) of FIG. 3. Here, the central region GC of the gas distribution unit 300 may be a remaining region except for the edge region GE of the gas distribution unit 300.

Here, the first temperature control unit 410 is installed in the central region GC of the gas distribution unit 300, and the second temperature control unit 420 is installed in the edge region GE of the gas distribution unit 300. Here, the first temperature control unit 410 increases the temperature of the central region GC of the gas distribution unit 300, and the second temperature control unit 420 increases the temperature of the edge region GE of the gas distribution unit 300. The second temperature control unit 420 may use a temperature controlling member that increases the temperature more rapidly than does the first temperature control unit 410.

As described above, the edge region CE of the cover 110 is heated at a relatively low temperature, and the central region CC of the cover 110 is heated at a relatively high temperature. However, the first temperature control unit 410 increases the temperature of the central region GC of the gas distribution unit 300, and the second temperature control unit 420 increases the temperature of the edge region GE of the gas distribution unit 300. Thus, when the temperature of the edge region GE of the gas distribution unit 300 is increased more rapidly than the temperature of the central region GC of the gas distribution unit 300, the edge region CE of the cover 110 and the central region CC of the cover 110 may have the uniform temperature more quickly.

In order to increase the temperature of the edge region GE of the gas distribution unit 300 more rapidly than the temperature of the central region GC of the gas distribution unit 300, the second temperature control unit 420 may heat the gas distribution unit 300 to a higher temperature than does the first temperature control unit 410. To this end, the first temperature control unit 410 may include a heat exchanger, and the second temperature control unit 420 may include a sheath heater.

That is, the first temperature control unit 410 may increase the temperature of the central region GC of the gas distribution unit 300 by allowing a heating fluid to flow in the central region GC of the gas distribution unit 300, and the second temperature control unit 420 may increase the temperature of the edge region GE of the gas distribution unit 300 by heating an electric heating wire buried in the edge region GE of the gas distribution unit 300.

Here, the first temperature control unit 410 may include a flow channel 414 provided to allow the heating fluid to flow inside the central region GC of the gas distribution unit 300, an inlet 412 for supplying the heating fluid to the flow channel 414, and an outlet 416 for discharging the heating fluid from the flow channel 414. In (b) of FIG. 3, two of first temperature control units 410 are provided and, each is illustrated as extending in one direction in the central region GC of the gas distribution unit 300. However, the number of first temperature control units 410 and the extension direction of the flow channel 414 may be diversely provided.

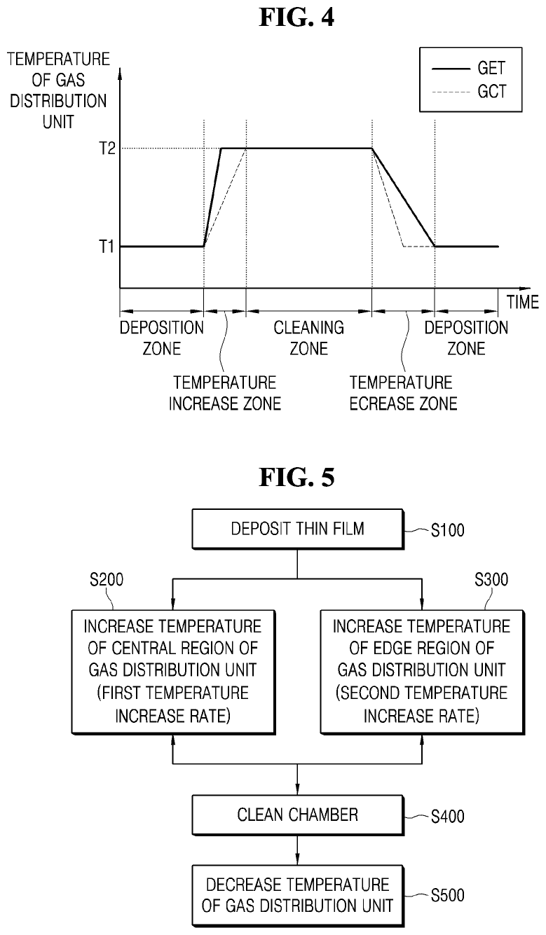

Also, the first temperature control unit 410 may decrease the temperature of the central region GC of the gas distribution unit 300. That is, the first temperature control unit 410 may cool the central region GC of the gas distribution unit 300 by supplying and discharging a cooling fluid through the inlet 412 and the outlet 416. This operation for cooling the central region GC of the gas distribution unit 300 is conducted to perform a thin film deposition process after the cleaning process is finished. This will be described later with reference to FIG. 4.

Also, the second temperature control unit 420 may include an electric heating wire buried inside the edge region GE of the gas distribution unit 300. In FIG. 3, one or two electric heating wires are illustrated as extending along the edge region GE of the gas distribution unit 300. However, the number of second temperature control units 420 and the extension direction of the electric heating wires may also be provided diversely.

Hereinafter, the temperature controlling for the gas distribution unit 300 will be described in more detail with reference to FIG. 4.

The thin film deposition process is performed in a thin film deposition zone. The thin film deposition process may be conducted by not heating the gas distribution unit 300 or by heating the central region GC of the gas distribution unit 300 and the edge region GE of the gas distribution unit 300 at the same temperature. That is, in the gas distribution unit 300 during the thin film deposition process, the central region GC of the gas distribution unit 300 and the edge region GE of the gas distribution unit 300 may be maintained at the same temperature. The temperature of the gas distribution unit 300 may have a first temperature T1 less than a thermal decomposition temperature of the process gas, for example, about 80° C. or less.

Described in more detail, a thin film is generally deposited by thermally decomposing the process gas on the substrate S during the thin film deposition process. Here, the temperature inside the chamber 100 may be controlled by heating of the substrate supporting unit 200 or heating of both the substrate supporting unit 200 and the gas distribution unit 300. Accordingly, the process gas is thermally decomposed on the substrate S and deposited as a thin film. Here, the thin film deposition process may be a process for depositing, on the substrate S, a zinc oxide doped with at least one of indium (In) or gallium (Ga), for example, IZO, GZO, IGZO, or the like.

Here, the temperature of the gas distribution unit 300 positioned inside the chamber 100 may be raised by the heating of the substrate supporting unit 200 or the heating of both the substrate supporting unit 200 and the gas distribution unit 300. However, in this case, the temperature of the gas distribution unit 300 has to be maintained at a temperature less than the thermal decomposition temperature of the process gas. When the temperature of the gas distribution unit 300 is increased to the thermal decomposition temperature of the process gas or higher, the process gas may be thermally decomposed inside the gas distribution unit 300 prior to arriving the substrate S. This thermally decomposed process gas may be accumulated inside the gas distribution unit 300 in the form of a large amount of byproduct. Also, the process gas thermally decomposed inside the gas distribution unit 300 is degraded. Thus, when this thermally decomposed and degraded raw gas is supplied from the gas distribution unit 300, a desired thin film may not be deposited on the substrate S. Accordingly, the heating of the substrate supporting unit 200 is limited such that the temperature of the gas distribution unit 300 is maintained at the first temperature T1 less than the thermal decomposition temperature of the raw gas.

In a temperature increase zone, the temperature of the gas distribution unit 300 inside the chamber 100 is controlled to a second temperature T2 higher than the first temperature T1 that is the temperature of the gas distribution unit 300 during the thin film deposition process. That is, after the thin film deposition process for depositing the thin film on the substrate S, the cleaning process is consecutively performed to clean the chamber 100 in situ while maintaining a vacuum without opening the chamber 100. A process for increasing the temperature of the gas distribution unit 300 is performed between the thin film deposition process and the cleaning process. This process for increasing the temperature of the gas distribution unit 300 is performed because the cleaning efficiency may be maximized when the temperature of the gas distribution unit 300 is high.

The process for increasing the temperature of the gas distribution unit 300 is performed such that a temperature increase rate of the edge region GE of the gas distribution unit 300 is higher than a temperature increase rate of the central region GC of the gas distribution unit 300. That is, the first temperature control unit 410 increases the temperature GCT of the central region GC of the gas distribution unit 300, and the second temperature control unit 420 increases the temperature GET of the edge region GE of the gas distribution unit 300. The second temperature control unit 420 increases the temperature GET of the edge region GE of the gas distribution unit 300 more rapidly than the temperature GCT of the central region GC of the gas distribution unit 300.

As described above, the chamber 100 is heated by the heating of the heater in the thin film deposition zone. However, since the substrate support 210 is provided in the lower central portion within the chamber 100, the amounts of the heat generated from the substrate support 210 and transmitted to the chamber 100 are different for regions. That is, the relatively small amount of heat is transmitted from the substrate support 210 to the edge region CE of the cover 110, which is the region adjacent to the side wall portion of the chamber 100 on the bottom surface of the cover 110, and thus the edge region CE is heated at the relatively low temperature. On the other hand, the relatively large amount of heat is transmitted from the substrate support 210 to the central region CC of the cover 110, which is the remaining region except for the edge region CE of the cover 110 on the bottom surface of the cover 110, and thus the central region CC is heated at the relatively high temperature.

Accordingly, in the temperature increase zone, the second temperature control unit 420 installed in the edge region GE of the gas distribution unit 300 increases the temperature more rapidly than does the first temperature control unit 410 installed in the central region GC of the gas distribution unit 300. Thus, the inside of the chamber 100 is uniformly heated. That is, the second temperature control unit 420 heats the gas distribution unit 300 more rapidly than does the first temperature control unit 410, and thus the temperature of the edge region CE of the cover 110 and the temperature of the central region CC of the cover 110 are quickly and uniformly increased.

In the temperature increase zone, the temperatures of the gas distribution unit 300 may be increased to the same temperature for regions, or the temperature of the edge region GE of the gas distribution unit 300 may be increased higher than the temperature of the central region GC of the gas distribution unit 300. This is because the temperature of the edge region CE of the cover 110, which is the region adjacent to the side wall portion of the chamber 100 on the bottom surface of the cover 110, is decreased more easily than that of the central region CC of the cover 110. However, even in a case where the temperature of the edge region GE of the gas distribution unit 300 is increased higher than the temperature of the central region GC of the gas distribution unit 300, it is desirable that the edge region CE of the cover 110 and the central region CC of the cover 110 are controlled to have approximately the uniform temperature.

As described above, the second temperature control unit 420 heats the gas distribution unit 300 more rapidly than does the first temperature control unit 410. Thus, when the first temperature control unit 410 reaches the second temperature T2, the edge region CE of the cover 110 and the central region CC of the cover 110 may have approximately the uniform temperature. Accordingly, when the first temperature control unit 410 reaches a target temperature, the cleaning process for cleaning the inside of the chamber 100 is performed.

In a cleaning zone, the inside of the chamber 100 is cleaned by supplying the cleaning gas from the gas distribution unit 300 to the inside of the chamber 100. During the cleaning process, the temperature of the gas distribution unit 300 is maintained at the second temperature T2 higher than the first temperature T1. Here, in the cleaning zone, the temperature of the gas distribution unit 300 may be maintained at about 200° C. or higher. In the cleaning zone, the cleaning gas is supplied from the gas distribution unit 300, and the cleaning gas is activated by plasma or the like to remove the byproduct inside the chamber 100. As described above, the thin film deposition process is a process for depositing, on the substrate S, the zinc oxide doped with at least one of indium (In) or gallium (Ga), for example, IZO, GZO, IGZO, or the like. Accordingly, the byproduct accumulated inside the chamber 100 may include the metal oxide such as the zinc oxide doped with at least one of indium (In) or gallium (Ga). The cleaning efficiency for the byproduct including the metal oxide may be maximized when the temperature of the gas distribution unit 300 is high. Thus, in a cleaning operation, the temperature of the gas distribution unit 300 is controlled to the second temperature T2 higher than the first temperature T1 that is a temperature of the gas distribution unit 300 when the thin film is deposited. Then, the gas distribution unit 300 cleans the chamber 100 in a state where the second temperature T2 is maintained.

In a temperature decrease zone, the temperature of the gas distribution unit 300, which has been increased to clean the chamber 100, is decreased again for the thin film deposition process. That is, in the temperature decrease zone, a process for decreasing the temperature of the gas distribution unit 300 is performed. As described above, the first temperature control unit 410 selectively allows the heating fluid or the cooling fluid to flow in the central region GC of the gas distribution unit 300, and the second temperature control unit 420 heats the electric heating wire in the edge region GE of the gas distribution unit 300. Thus, during the process for decreasing the temperature of the gas distribution unit 300, the first temperature control unit 410 may allow the cooling fluid to flow in the central region GC of the gas distribution unit 300, thereby cooling the gas distribution unit 300. Also, the second temperature control unit 420 does not have a separate cooling function and thus may be maintained in a state where the heating of the electric heating wire is stopped. Accordingly, the first temperature control unit 410 may decrease the temperature of the gas distribution unit 300 more rapidly than does the second temperature control unit 420.

As described above, when the temperature of the gas distribution unit 300 is controlled from the second temperature T2 to the first temperature T1 in the temperature decrease zone, the thin film deposition process is performed again in the thin film deposition zone.

Hereinafter, a method for processing a substrate according to the present disclosure will be described in detail with reference to FIG. 5. In describing the method for processing a substrate according to the present disclosure, a description overlapping with that of the substrate processing device described above will be omitted.

FIG. 5 is a view schematically showing a method for processing a substrate according to an embodiment of the present disclosure.

Referring to FIG. 5, a method for processing a substrate (hereinafter, referred to as a substrate processing method) according to an embodiment of the present disclosure includes an operation (S100) of depositing a thin film on a substrate S in a chamber 100 in which a gas distribution unit 300 is provided, an operation (S200) of increasing a temperature of a central region GC of the gas distribution unit 300 at a first temperature increase rate, an operation (S300) of increasing a temperature of an edge region GE of the gas distribution unit 300 at a second temperature increase rate higher than the first temperature increase rate, and an operation (S400) of supplying a cleaning gas into the chamber 100 to clean the chamber 100.

In the operation (S100) of depositing the thin film on the substrate S, a process gas is supplied onto the substrate S through the gas distribution unit 300 inside the chamber 100 in which the gas distribution unit 300 is provided, thereby depositing the thin film on the substrate S.

The operation (S100) of depositing the thin film on the substrate S may be conducted by not heating the gas distribution unit 300 or by heating the central region GC of the gas distribution unit 300 and the edge region GE of the gas distribution unit 300 at the same temperature. That is, in a thin film deposition zone for the gas distribution unit 300, the central region GC of the gas distribution unit 300 and the edge region GE of the gas distribution unit 300 may be maintained at the same temperature. The temperature of the gas distribution unit 300 may have a first temperature T1 which is a temperature less than a thermal decomposition temperature of the process gas, for example, about 80° C. or less.

Described in more detail, a thin film is generally deposited by thermally decomposing the process gas on the substrate S during a thin film deposition process. Here, the temperature inside the chamber 100 may be controlled by heating of the substrate supporting unit 200 or heating of both the substrate supporting unit 200 and the gas distribution unit 300. Accordingly, the process gas is thermally decomposed on the substrate S and deposited as a thin film. Here, the thin film deposition process may be a process for depositing, on the substrate S, a zinc oxide doped with at least one of indium (In) or gallium (Ga), for example, IZO, GZO, IGZO, or the like.

Here, the temperature of the gas distribution unit 300 positioned inside the chamber 100 may be raised by the heating of the substrate supporting unit 200 or the heating of both the substrate supporting unit 200 and the gas distribution unit 300. However, in this case, the temperature of the gas distribution unit 300 should be maintained at a temperature less than the thermal decomposition temperature of the process gas. When the temperature of the gas distribution unit 300 is increased to the thermal decomposition temperature of the process gas or higher, the process gas may be thermally decomposed inside the gas distribution unit 300 prior to arriving the substrate S. This thermally decomposed process gas may be accumulated inside the gas distribution unit 300 in the form of a large amount of byproduct. Also, the process gas thermally decomposed inside the gas distribution unit 300 is degraded. Thus, when this thermally decomposed and degraded raw gas is supplied from the gas distribution unit 300, a desired thin film may not be deposited on the substrate S. Accordingly, the heating of the substrate supporting unit 200 is limited such that the temperature of the gas distribution unit 300 is maintained at the temperature less than the thermal decomposition temperature of the raw gas.

After the operation (S100) of depositing the thin film on the substrate S, the temperature of the gas distribution unit 300 is increased. That is, after the operation (S100) of depositing the thin film on the substrate S, the temperature of the gas distribution unit 300 is increased such that temperature increase rates of the gas distribution unit 300 become different for regions. The increasing of temperature may include the operation (S200) of increasing the temperature of the central region of the gas distribution unit at the first temperature increase rate and the operation (S300) of increasing the temperature of the edge region of the gas distribution unit at the second temperature increase rate higher than the first temperature increase rate. Here, the operation (S200) of increasing the temperature of the central region and the operation (S300) of increasing the temperature of the edge region may be performed simultaneously.

After the operation (S100) of depositing the thin film on the substrate S, the temperature of the gas distribution unit 300 inside the chamber 100 is controlled to a second temperature T2 higher than the first temperature T1 that is the temperature of the gas distribution unit 300 during the thin film deposition process.

That is, after the thin film deposition process for depositing the thin film on the substrate S, the cleaning process is consecutively performed to clean the chamber 100 in situ while maintaining a vacuum without opening the chamber 100. A process for increasing the temperature of the gas distribution unit 300 is performed between the thin film deposition process and the cleaning process. This process for increasing the temperature of the gas distribution unit 300 is performed because the cleaning efficiency may be maximized when the temperature of the gas distribution unit 300 is high.

As described above, the process for increasing the temperature of the gas distribution unit 300 is performed such that a temperature increase rate of the edge region GE of the gas distribution unit 300 is higher than a temperature increase rate of the central region GC of the gas distribution unit 300. That is, a first temperature control unit 410 increases the temperature of the central region GC of the gas distribution unit 300, and a second temperature control unit 420 increases the temperature of the edge region GE of the gas distribution unit 300. The second temperature control unit 420 increases the temperature of the edge region GE of the gas distribution unit 300 more rapidly than the temperature of the central region GC of the gas distribution unit 300.

In the operation (S100) of depositing the thin film, the chamber 100 is heated by heating of a heater. However, since a substrate support 210 is provided in a lower central portion within the chamber 100, amounts of the heat generated from the substrate support 210 and transmitted to the chamber 100 are different for regions. That is, a relatively small amount of heat is transmitted from the substrate support 210 to an edge region CE of a cover 110, which is the region adjacent to the side wall portion of the chamber 100 on the bottom surface of the cover 110, and thus the edge region CE is heated at a relatively low temperature. On the other hand, a relatively large amount of heat is transmitted from the substrate support 210 to a central region CC of the cover 110, which is the remaining region except for the edge region CE of the cover 110 on the bottom surface of the cover 110, and thus the central region CC is heated at a relatively high temperature.

Accordingly, during the process of increasing the temperature of the gas distribution unit 300, the second temperature control unit 420 installed in the edge region GE of the gas distribution unit 300 increases the temperature more rapidly than does the first temperature control unit 410 installed in the central region GC of the gas distribution unit 300. Thus, the inside of the chamber 100 is uniformly heated. That is, the second temperature control unit 420 heats the gas distribution unit 300 more rapidly than does the first temperature control unit 410, and thus the temperature of the edge region CE of the cover 110 and the temperature of the central region CC of the cover 110 are quickly and uniformly increased.

In the operation (S400) of cleaning the chamber 100, the cleaning gas is supplied into the chamber 100 to clean the chamber 100. In the operation (S400) of cleaning the chamber 100, the temperature of the gas distribution unit 300 is maintained at the second temperature T2 higher than the first temperature T1. Here, in a cleaning zone, the temperature of the gas distribution unit 300 may be maintained at about 200° C. or higher. In the cleaning zone, the cleaning gas is supplied from the gas distribution unit 300, and the cleaning gas is activated by plasma or the like to remove a byproduct inside the chamber 100. As described above, the thin film deposition process is a process for depositing, on the substrate S, the zinc oxide doped with at least one of indium (In) or gallium (Ga), for example, IZO, GZO, IGZO, or the like. Accordingly, the byproduct accumulated inside the chamber 100 may include the metal oxide such as the zinc oxide doped with at least one of indium (In) or gallium (Ga). The cleaning efficiency for the byproduct including the metal oxide may be maximized when the temperature of the gas distribution unit 300 is high. Thus, in the cleaning operation, the temperature of the gas distribution unit 300 is controlled to the second temperature T2 higher than the first temperature T1 that is a temperature of the gas distribution unit 300 when the thin film is deposited. Then, the gas distribution unit 300 cleans the chamber 100 in a state where the second temperature T2 is maintained.

Here, the operation (S400) of cleaning the chamber 100 may be performed while the temperatures of the gas distribution unit 300 are maintained constant for all the regions or while the temperature of the edge region GE of the gas distribution unit 300 is maintained higher than that of the central region GC of the gas distribution unit 300. This is because the temperature of the edge region CE of the cover 110, which is the region adjacent to the side wall portion of the chamber 100 on the bottom surface of the cover 110, is decreased more easily than that of the central region CC of the cover 110. However, even in a case where the temperature of the edge region GE of the gas distribution unit 300 is increased higher than the temperature of the central region GC of the gas distribution unit 300, it is desirable that the edge region CE of the cover 110 and the central region CC of the cover 110 are controlled to have approximately the uniform temperature.

The substrate processing method according to an embodiment of the present disclosure may further include an operation (S500) of decreasing the temperature of the gas distribution unit 300 after the operation (S400) of cleaning the chamber 100. Here, in the operation (S500) of decreasing the temperature of the gas distribution unit 300, the temperature of the central region GC of the gas distribution unit 300 may be decreased by allowing a cooling fluid to flow in the central region GC of the gas distribution unit 300, and the temperature of the edge region GE of the gas distribution unit 300 may be decreased by stopping heating of an electric heating wire buried in the edge region GE of the gas distribution unit 300.

In the operation (S500) of decreasing the temperature of the gas distribution unit 300, the temperature of the gas distribution unit 300, which has been increased to clean the chamber 100, is decreased again for the thin film deposition process. That is, in a temperature decrease zone, a process for decreasing the temperature of the gas distribution unit 300 is performed. As described above, the first temperature control unit 410 selectively allows a heating fluid or a cooling fluid to flow in the central region GC of the gas distribution unit 300, and the second temperature control unit 420 heats the electric heating wire in the edge region GE of the gas distribution unit 300. Thus, during the process for decreasing the temperature of the gas distribution unit 300, the first temperature control unit 410 may allow the cooling fluid to flow in the central region GC of the gas distribution unit 300, thereby cooling the gas distribution unit 300. Also, the second temperature control unit 420 does not have a separate cooling function and thus may be maintained in a state where the heating of the electric heating wire is stopped. Accordingly, the first temperature control unit 410 may decrease the temperature of the gas distribution unit 300 more rapidly than does the second temperature control unit 420. As described above, when the temperature of the gas distribution unit 300 is controlled from the second temperature T2 to the first temperature T1 in the operation (S500) of decreasing the temperature of the gas distribution unit 300, the operation (S100) of depositing the thin film may be performed again.

As described above, in the substrate processing device and the substrate processing method according to the embodiment of the present disclosure, the temperature changing rates of the gas distribution unit 300 are controlled differently for the regions, and thus the inside of the chamber 100 having non-uniform temperature distribution during the thin film deposition process may be quickly controlled to the uniform temperature prior to performing the cleaning process.

Accordingly, it is possible to maximize the cleaning efficiency of the cleaning process for removing the byproduct accumulated inside the chamber 100, and particularly, it is possible to efficiently clean the byproduct including the metal accumulated inside the chamber 100 of the substrate processing device that performs MOCVD.

Also, in the substrate processing device and the substrate processing method according to the embodiment of the present disclosure, it is possible to perform the in-situ cleaning without opening the chamber 100 in the chemical vapor deposition process that requires frequent cleaning. Thus, the operation efficiency may be improved, and the high reproducibility and operating ratio of equipment may be ensured.

Although preferred embodiments of the present disclosure have been described and illustrated above using specific terms, these terms are intended only to clearly describe the present disclosure, and it will be apparent that the embodiments and the terms described in the present disclosure can be changed and modified diversely without departing from the technical spirit and scope of the appended claims. Such modified embodiments should not be understood as being provided separately from the spirit and scope of the present disclosure but be considered as falling within the claims of the present disclosure.

1. A device for processing a substrate, the device comprising:
a chamber;
a substrate supporting unit provided inside the chamber and configured to support the substrate provided inside the chamber;
a gas distribution unit provided inside the chamber to face the substrate supporting unit and configured to distribute a process gas toward the substrate supporting unit;
a first temperature control unit installed in a central region of the gas distribution unit and configured to increase a temperature of the central region; and
a second temperature control unit installed in an edge region of the gas distribution unit and configured to increase a temperature of the edge region more rapidly than the temperature of the central region.

2. A device for processing a substrate, the device comprising:
a chamber;
a substrate supporting unit provided inside the chamber and configured to support the substrate provided inside the chamber;
a gas distribution unit provided inside the chamber to face the substrate supporting unit and configured to distribute a process gas toward the substrate supporting unit;
a first temperature control unit installed in a central region of the gas distribution unit and configured to increase or decrease a temperature of the central region; and
a second temperature control unit installed in an edge region of the gas distribution unit and configured to increase a temperature of the edge region.

3. The device of claim 1, wherein the second temperature control unit heats the gas distribution unit to a higher temperature than does the first temperature control unit.

4. The device of claim 1, wherein the first temperature control unit comprises:
a flow channel configured to allow a temperature controlling fluid to flow inside the central region;
an inlet configured to supply the temperature controlling fluid to the flow channel; and
an outlet configured to discharge the temperature controlling fluid from the flow channel.

5. The device of claim 4, wherein the second temperature control unit comprises an electric heating wire buried inside the edge region.

6. A method for processing a substrate, the method comprising:
depositing a thin film on the substrate in a chamber in which a gas distribution unit is provided;
increasing a temperature of a central region of the gas distribution unit at a first temperature increase rate;
increasing a temperature of an edge region of the gas distribution unit at a second temperature increase rate higher than the first temperature increase rate; and
supplying a cleaning gas into the chamber to clean the chamber.

7. The method of claim 6, wherein the increasing of the temperature of the central region and the increasing of the temperature of the edge region are performed simultaneously.

8. The method of claim 6, wherein the increasing of the temperature of the central region comprises allowing a heating fluid to flow in the central region, thereby increasing the temperature of the central region,
wherein the increasing of the temperature of the edge region comprises heating an electric heating wire buried in the edge region, thereby increasing the temperature of the edge region.

9. The method of claim 6, wherein the cleaning of the chamber is performed while the temperatures of the gas distribution unit are maintained constant for all the regions or while the temperature of the edge region is maintained higher than that of the central region.

10. The method of claim 6, wherein a byproduct on the thin film or inside the chamber comprises a metal oxide.
